(19) United States
(12) Patent Application Publication
(10) Pub. No.: US 2025/0016986 A1
(43) Pub. Date: Jan. 9, 2025

(54) SEMICONDUCTOR DEVICES HAVING PERIPHERAL CONTACT PLUGS

(71) Applicant: SAMSUNG ELECTRONICS CO., LTD., Suwon-si (KR)

(72) Inventors: Heonjun Ha, Suwon-si (KR); Jungun Kim, Suwon-si (KR); Injae Bae, Suwon-si (KR)

(21) Appl. No.: 18/666,612

(22) Filed: May 16, 2024

(30) Foreign Application Priority Data
Jul. 5, 2023 (KR) 10-2023-0087018

(51) Int. Cl. H10B 12/00

(52) U.S. Cl. CPC H10B 12/48; H10B 12/315

(57) ABSTRACT

An example semiconductor device includes a substrate including a cell array region and a connection region, a peripheral circuit layer, a bit line disposed on the peripheral circuit layer in the cell array region, a first upper interconnection disposed in the connection region on a same height as the bit line is from the substrate, at least one lower interconnection layer disposed between the peripheral circuit layer and the bit line and between the peripheral circuit layer and the first upper interconnection, a bit line insulating layer surrounding the bit line in the cell array region and the first upper interconnection in the connection region, an upper structure disposed on the bit line and the first upper interconnection, an information storage structure disposed on the upper structure in the cell array region, and a lower contact plug electrically connected to the at least one lower interconnection layer.

### CROSS-REFERENCE TO RELATED APPLICATION

This application claims benefit of priority to Korean Patent Application No. 10-2023-0087018 filed on Jul. 5, 2023, in the Korean Intellectual Property Office, the disclosure of which is incorporated herein by reference in its entirety.

### BACKGROUND

In line with growing demand for high performance, high speed, and/or multifunctionality of semiconductor devices, the degree of integration of semiconductor devices has increased. In manufacturing semiconductor devices with fine patterns corresponding to the trend for high integration of semiconductor devices, it is necessary to implement patterns having a fine width or a fine distance.

### SUMMARY

The present disclosure relates to semiconductor devices, including a semiconductor device including lower interconnection layers arranged on a peripheral circuit layer and an upper interconnection layer, and lower contact plugs connected to the lower interconnection layers.

In general, according to some aspects, a semiconductor device includes a substrate including a cell array region and a connection region, a peripheral circuit layer disposed on the substrate and including a circuit element, a bit line disposed on the peripheral circuit layer in the cell array region, a first upper interconnection disposed on the same level as that of the bit line in the connection region, at least one lower interconnection layer disposed between the peripheral circuit layer and the bit line and between the peripheral circuit layer and the first upper interconnection, a bit line insulating layer surrounding the bit line in the cell array region and surrounding the first upper interconnection in the connection region, an upper structure disposed on the bit line and the first upper interconnection and including an upper insulating structure, an information storage structure disposed on the upper structure in the cell array region, and a lower contact plug electrically connected to the at least one lower interconnection layer through the bit line insulating layer in the connection region.

In general, according to some other aspects, a semiconductor device includes a substrate including a cell array region and a connection region, a peripheral circuit layer disposed on the substrate and including a circuit element, a bit line disposed on the peripheral circuit layer in the cell array region, a first upper interconnection disposed on the same level as that of the bit line in the connection region, a lower interconnection layer disposed between the peripheral circuit layer and the bit line and between the peripheral circuit layer and the first upper interconnection, the lower interconnection layer including a lower interconnection, a bit line insulating layer surrounding the bit line in the cell array region and surrounding the first upper interconnection in the connection region, an upper structure disposed on the bit line and the first upper interconnection and including an upper insulating structure, an information storage structure disposed on the upper structure in the cell array region, an upper interlayer insulating layer covering the information storage structure in the cell array region and covering the upper insulating structure in the connection region, a lower contact plug extending in a vertical direction from an upper surface of the upper interlayer insulating layer in the connection region and passing through the bit line insulating layer and contacting the lower interconnection, and a first upper contact plug extending in the vertical direction from an upper surface of the upper interlayer insulating layer and contacting the first upper interconnection.

In general, according to some other aspects, a semiconductor device includes a substrate including a cell array region and a connection region, a peripheral circuit layer disposed on the substrate and including a circuit element, a first lower interconnection layer disposed on the peripheral circuit layer and including a first lower interconnection, a second lower interconnection layer disposed on the first lower interconnection layer and including a second lower interconnection layer, a bit line disposed on the second lower interconnection layer in the cell array region, a first upper interconnection disposed on the same level as that of the bit line in the connection region, a bit line insulating layer surrounding the bit line in the cell array region and surrounding the first upper interconnection in the connection region, an upper structure disposed on the bit line and the first upper interconnection and including a landing pad and an upper insulating structure surrounding the landing pad, a second upper interconnection disposed on the same level as that of the landing pad in the connection region, an information storage structure disposed on the upper structure in the cell array region, an upper interlayer insulating layer covering the information storage structure in the cell array region and covering the upper insulating structure in the connection region, and a first lower contact plug passing through the upper interlayer insulating layer, the upper insulating structure, and the bit line insulating layer and contacting the first lower interconnection in the connection region.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a plan view of a semiconductor device according to an example implementation

FIG. 2A is an example vertical cross-sectional view of the semiconductor device illustrated in FIG. 1 taken along line I-I′

FIG. 2B is an example vertical cross-sectional view of the semiconductor device illustrated in FIG. 1 taken along line II-II′

FIG. 3 is an example enlarged view of a portion of the semiconductor device illustrated in FIG. 2A

FIGS. 4A and 4B are vertical cross-sectional views of a semiconductor device according to an example implementation

FIGS. 5A and 5B are vertical cross-sectional views of a semiconductor device according to an example implementation

FIG. 6 is an example enlarged view of a portion of the semiconductor device illustrated in FIG. 5A

FIGS. 7A and 7B are vertical cross-sectional views of a semiconductor device according to an example implementation

FIG. 8 is an example enlarged view of a portion of the semiconductor device illustrated in FIG. 7A

FIG. 9 is a vertical cross-sectional view of a semiconductor device according to an example implementation.

FIGS. 10A to 15B are vertical cross-sectional views illustrating a sequential process of a method of manufacturing a semiconductor device according to an example implementation.

### DETAILED DESCRIPTION

Hereinafter, example implementations will be described with reference to the accompanying drawings.

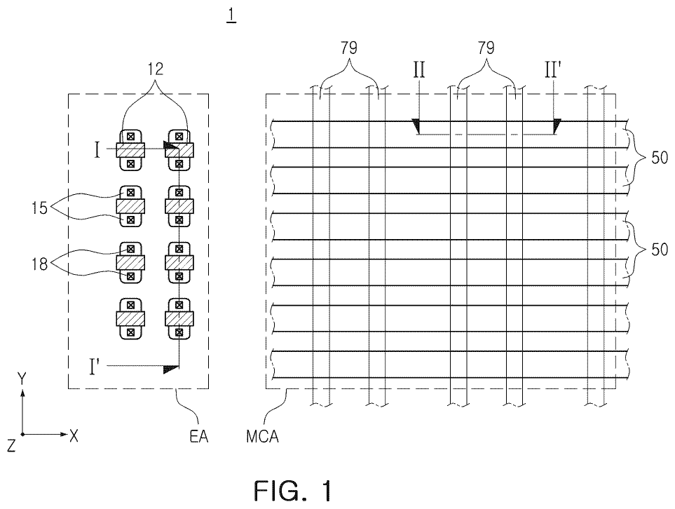

FIG. 1 is a plan view of a semiconductor device according to an example implementation.

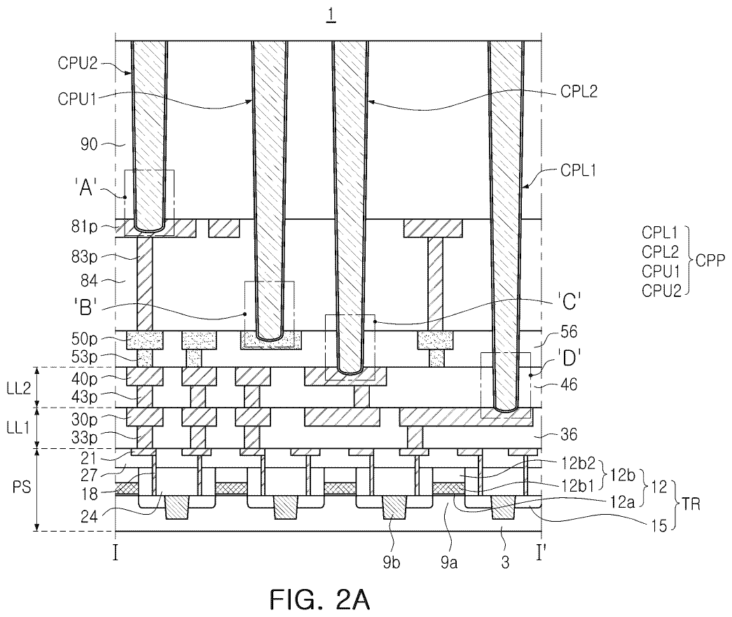

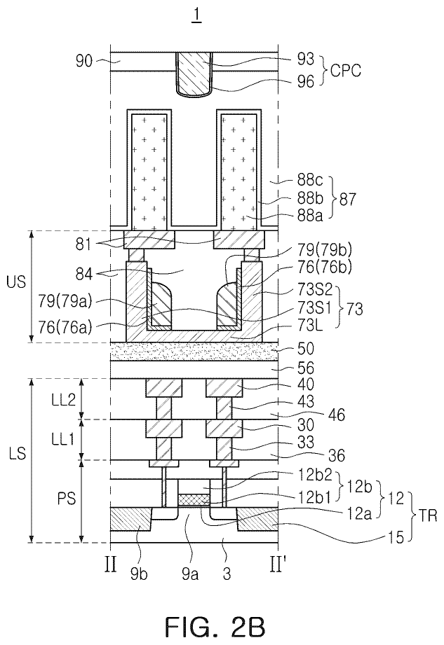

FIG. 2A is a vertical cross-sectional view of the semiconductor device illustrated in FIG. 1 taken along line I-I′. FIG. 2B is a vertical cross-sectional view of the semiconductor device illustrated in FIG. 1 taken along line II-II′.

Referring to FIGS. 1 to 2B, a semiconductor device 1 according to an example implementation includes a lower structure LS, a bit line 50, an upper structure US, an information storage structure 87, an upper interlayer insulating layer 90, a cell contact plug CPC, and a peripheral contact plug CPP.

The lower structure LS may include a peripheral circuit layer PS, a first lower interconnection layer LL1 and a second lower interconnection layer LL2. The peripheral circuit layer PS may include a circuit element TR disposed on the substrate 3. The circuit element TR may include a word line driver, a sense amplifier, row and column decoders, and control circuits. The substrate 3 may include a cell array region MCA and a connection region EA.

The substrate 3 may include a semiconductor material, such as a group IV semiconductor, a group III-V compound semiconductor, or a group II-VI compound semiconductor. For example, the group IV semiconductor may include silicon, germanium or silicon-germanium. The substrate 3 may include a silicon substrate, a silicon on insulator (SOI) substrate, a germanium substrate, a germanium on insulator (GOI) substrate, a silicon-germanium substrate, or a substrate including an epitaxial layer.

The circuit element TR may be disposed in the cell array region MCA and the connection region EA. The circuit element TR may include a peripheral transistor. For example, the peripheral transistor may include a gate structure 12 disposed on a peripheral active region 9a defined by a device isolation region 9b in the substrate 3 and peripheral source/drain regions 15 disposed in the peripheral active region 9a disposed on both sides of the gate structure 12.

The gate structure 12 may include a peripheral gate electrode 12b and a peripheral gate dielectric layer 12a between the peripheral gate electrode 12b and the peripheral active region 9a. The peripheral gate electrode 12b may include at least two conductive layers, for example, a first conductive layer 12b1 and a second conductive layer 12b2 on the first conductive layer 12b1.

The peripheral circuit layer PS may further include a peripheral plug 18, a peripheral interconnection 21, a first peripheral insulating layer 24, and a second peripheral insulating layer 27. The peripheral plug 18 may be connected to the peripheral source/drain region 15 and may extend vertically, and the peripheral interconnection 21 may be disposed on the peripheral plug 18. The peripheral interconnection 21 may be electrically connected to the circuit element TR through the peripheral plug 18. The first peripheral insulating layer 24 may surround side surfaces of the peripheral gate electrode 12b and the peripheral plug 18. The second peripheral insulating layer 27 may be disposed on the first peripheral insulating layer 24 and may surround the peripheral plug 18 and the peripheral interconnection 21. An upper surface of the second peripheral insulating layer 27 may be coplanar with an upper surface of the peripheral interconnection 21.

The first lower interconnection layer LL1 may be disposed on the peripheral circuit layer PS. In the cell array region MCA, the first lower interconnection layer LL1 may include a first lower interconnection 30 and a first lower plug 33. The first lower plug 33 may extend vertically and be connected to a corresponding peripheral interconnection 21. The first lower interconnections 30 may extend in a horizontal direction, and at least one of the first lower interconnections 30 may be electrically connected to a corresponding circuit element TR through a corresponding first lower plug 33. In the connection region EA, the first lower interconnection layer LL1 may include a first lower interconnection 30p and a first lower plug 33p. The first lower plug 33p may be connected to the corresponding peripheral interconnection 21, and the first lower interconnection 30p may be electrically connected to the corresponding circuit element TR through the first lower plug 33p. The first lower interconnection layer LL1 may include a first lower insulating layer 36 surrounding the first lower interconnections 30 and 30p and the first lower plugs 33 and 33p. The first lower insulating layer 36 may include silicon oxide, silicon nitride, silicon oxynitride, low dielectric, or combinations thereof.

The second lower interconnection layer LL2 may be disposed on the first lower interconnection layer LL1. In the cell array region MCA, the second lower interconnection layer LL2 may include a second lower interconnection 40 and a second lower plug 43. In the connection region EA, the second lower interconnection layer LL2 may include a second lower interconnection 40p and a second lower plug 43p. The second lower interconnection layer LL2 may include a second lower insulating layer 46 surrounding the second lower interconnections 40 and 40p and the second lower plugs 43 and 43p. The second lower interconnection layer LL2 may have a structure the same as or similar to the first lower interconnection layer LL1. The second lower interconnection layer LL2 may be electrically connected to the peripheral circuit layer PS through the first lower interconnection layer LL1. At least one of the first lower interconnections 30p may be electrically connected to at least one of the second lower interconnections 40p through the corresponding second lower plug 43p.

In some implementations, the first lower interconnection 30p, the first lower plug 33p, the second lower interconnection 40p, and the second lower plug 43p may include a metal layer and a barrier layer covering side and lower surfaces of the metal layer. The barrier layer may include at least one of TiN, TaN, WN, TiSiN, TaSiN, or RuTiN, and the metal layer may include a metal material, such as W or Mo.

The bit line 50 may be disposed on the second lower interconnection layer LL2 in the cell array region MCA. The bit lines 50 may extend in a first horizontal direction X and may be spaced apart from each other in a second horizontal direction Y. The first horizontal direction X and the second horizontal direction Y may be perpendicular to each other. The semiconductor device 1 may further include a cell connection plug 53 disposed below the bit line 50 and a bit line insulating layer 56 surrounding the bit line 50 and the cell connection plug 53. The bit line 50 may be electrically connected to the second lower interconnection layer LL2 through the cell connection plug 53. The bit line 50 may include doped polysilicon, metal, conductive metal nitride, metal-semiconductor compound, metal compound, conductive metal oxide, graphene, carbon nanotube, or combinations thereof.

Although not shown, the semiconductor device 1 in the cell array region MCA may further include shield patterns extending in the first horizontal direction X and spaced apart from each other in the second horizontal direction Y. The shield patterns may be alternately arranged with the bit lines 50 in the second horizontal direction Y. The shield patterns may reduce capacitance between bit lines 50.

The semiconductor device 1 may further include a first upper interconnection 50p and a first peripheral plug 53p disposed in the connection region EA. The first upper interconnection 50p may be electrically connected to the second lower interconnection layer LL2 through the first peripheral plug 53p. The bit line insulating layer 56 may extend into the connection region EA to surround the first upper interconnection 50p and the first peripheral plug 53p. The first upper interconnection 50p may be disposed on the same level as that of the bit line 50, and the first peripheral plug 53p may be disposed on the same level as that of the cell connection plug 53. The first upper interconnection 50p may include the same material as that of the bit line 50, and the first peripheral plug 53p may include the same material as that of the cell connection plug 53. The bit line insulating layer 56 may include silicon oxide, silicon nitride, silicon oxynitride, low dielectric, or combinations thereof.

In some implementations, the bit line 50, the cell connection plug 53, the first upper interconnection 50p, and the first peripheral plug 53p may include a metal layer and a barrier layer covering side and lower surfaces of the metal layer. The barrier layer may include at least one of TiN, TaN, WN, TiSiN, TaSiN, or RuTiN, and the metal layer may include a metal material, such as W or Mo.

The upper structure US may be disposed on the bit line 50 in the cell array region MCA. The upper structure US may include a channel structure 73, word lines 79, an upper insulating structure 84, a second upper interconnection 81p, and a second peripheral plug 83p.

The channel structure 73 may include a horizontal portion 73L in contact with and electrically connected to the bit line 50 and a first vertical channel portion 73S1 and a second vertical channel portion 73S2 extending in a vertical direction Z from both sides of the horizontal portion 73L of the first horizontal direction X. The vertical direction Z may be a direction, perpendicular to an upper surface of the substrate 3.

The channel structure 73 may be formed of a semiconductor material, such as silicon. The channel structure 73 may be formed of monocrystalline silicon or polysilicon. However, the channel structure 73 is not limited to semiconductor materials, such as silicon, and may be formed of other semiconductor materials usable as a channel region of a transistor. For example, the channel structure 73 may include an oxide semiconductor layer or a two-dimensional material layer that may be used as a channel region of a transistor.

The oxide semiconductor layer may be indium gallium zinc oxide (IGZO). However, the example implementation is not limited thereto. For example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), and zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), Indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

The two-dimensional material layer may include at least one of a transition metal dichalcogenide (TMD) material layer, a black phosphorous material layer, and a hexagonal boron-nitride (hBN) material layer, which may have semiconductor characteristics. For example, the two-dimensional material layer may include at least one of BiOSe, Crl, WSe2, MoS2, TaS, WS, SnSe, ReS, β-SnTe, MnO, AsS, P (black), InSe, h-BN, GaSe, GaN, SrTiO, Mxene, and Janus 2D materials that may form two-dimensional materials.

Each of the word lines 79 may extend in the second horizontal direction Y. A pair of word lines 79a and 79b among the word lines 79 may vertically overlap the horizontal portion 73L of the channel structure 73 and may be disposed between the first and second vertical channel portions 73S1 and 73S2 of the channel structure 73. The pair of word lines 79a and 79b may include a first word line 79a facing the first vertical channel portion 73S1 and a second word line 79b facing the second vertical channel portion 73S2.

The upper structure US may further include dielectric structures 76 between the word lines 79 and the channel structure 73. The dielectric structures 76 may include a first dielectric structure 76a that may be disposed between the first word line 79a and the first vertical channel portion 73S1 and between the first word line 79a and the horizontal portion 73L and a second dielectric structure 76b that may be disposed between the second word line 79b and the second vertical channel portion 73S2 and between the second word line 79b and the horizontal portion 73L.

In an example, each of the dielectric structures 76 may be a tunnel dielectric layer that does not include an information storage layer. For example, each of the dielectric structures 76 may include at least one of silicon oxide and a high-k dielectric. The high-K dielectric may include a metal oxide or a metal oxynitride. For example, the high dielectric may be formed of HfO₂, HfSiO, HfSION, HfTaO, HfTIO, HfZrO, ZrO₂, Al₂O₃, or combinations thereof, but is not limited thereto. Each of the dielectric structures 76 may be formed of a single layer or multiple layers of the aforementioned materials.

In another example, each of the dielectric structures 76 may include an information storage layer and a dielectric layer. For example, each of the dielectric structures 76 may include a ferroelectric layer that may have polarization characteristics according to an electric field and may have remnant polarization due to a dipole even in the absence of an external electric field. Data may be recorded using the polarization state in the ferroelectric layer. Accordingly, each of the dielectric structures 76 may include a ferroelectric layer that may be referred to as an information storage layer. The ferroelectric layer, which may be the information storage layer, may include an Hf-based compound, a Zr-based compound, and/or an Hf—Zr-based compound. For example, the Hf-based compound may be an HfO-based ferroelectric material, the Zr-based compound may include a ZrO-based ferroelectric material, and the Hf—Zr-based compound may include a hafnium zirconium oxide (HZO)-based ferroelectric material. The ferroelectric layer, which may be the information storage layer, may include a ferroelectric material doped with impurities, for example, at least one of C, Si, Mg, Al, Y, N, Ge, and Sn, Gd, La, Sc, and Sr. For example, the ferroelectric layer, which may be the information storage layer, may be a material formed by doping at least one of HfO₂, ZrO₂, and HzrO with at least one of impurities C, Si, Mg, Al, Y, N, Ge, Sn, Gd, La, Sc and Sr.

In the dielectric structures 76, the information storage layer is not limited to the aforementioned types of materials and may include a material capable of storing information.

The upper structure US may further include landing pads 81 electrically connected to and contacting the first and second vertical channel portions 73S1 and 73S2 on the channel structure 73. The landing pads 81 may be formed of a conductive material.

The upper insulating structure 84 may be disposed on the bit lines 50 in the cell array region MCA. The upper insulating structure 84 may be disposed on the first upper interconnection 50p and the bit line insulating layer 56 in the connection region EA. The upper insulating structure 84 may cover a side surface of a structure including the channel structure 73, the word lines 79, and the landing pads 81.

The second upper interconnection 81p may be disposed on the same level as that of the landing pads 81 in the connection region EA. For example, an upper surface of the second upper interconnection 81p may be located on the same level as that of upper surfaces of the landing pads 81. The second peripheral plug 83p may extend in the vertical direction Z and may connect one of the second upper interconnections 81p to one of the first upper interconnections 50p. The second upper interconnection 81p may include the same material as that of the landing pads 81. The upper insulating structure 84 may surround side surfaces of the second upper interconnection 81p and the second peripheral plug 83p in the connection region EA. The upper insulating structure 84 may include silicon oxide, silicon nitride, silicon oxynitride, low dielectric, or combinations thereof. For example, the upper interlayer insulating layer 90 may include silicon oxide.

The information storage structure 87 may be disposed on the upper structure US in the cell array region MCA. The information storage structure 87 may include first electrodes 88a electrically connected to and contacting the landing pads 81, a second electrode 88c on the first electrodes 88a, and a dielectric layer 88b between the first electrodes 88a and the second electrode 88c.

In an example, the information storage structure 87 may be a capacitor storing information in DRAM. For example, the dielectric layer 88b of the information storage structure 87 may be a capacitor dielectric layer of DRAM, and the dielectric layer 87b may include a high-K dielectric layer, silicon oxide, silicon nitride, silicon oxynitride, or combinations thereof.

In another example, the information storage structure 87 may be a structure for storing information of a memory different from DRAM. For example, the information storage structure 87 may be a capacitor of a ferroelectric memory (FeRAM). For example, the dielectric layer 88b may be a ferroelectric layer capable of recording data using a polarization state. In another example, the dielectric layer 88b may include a lower dielectric layer and a ferroelectric layer on the lower dielectric layer. Here, the lower dielectric layer may include at least one of silicon oxide, silicon oxynitride, silicon nitride, and a high-K dielectric.

In some implementations, when the dielectric structures 76 include an information storage layer, the information storage structure 87 may be omitted.

The upper interlayer insulating layer 90 may cover the information storage structure 87 in the cell array region MCA and may cover the second upper interconnection 81p in the connection region EA. The upper interlayer insulating layer 90 may include silicon oxide, silicon nitride, silicon oxynitride, low-K dielectric, or combinations thereof. For example, the upper interlayer insulating layer 90 may include silicon oxide.

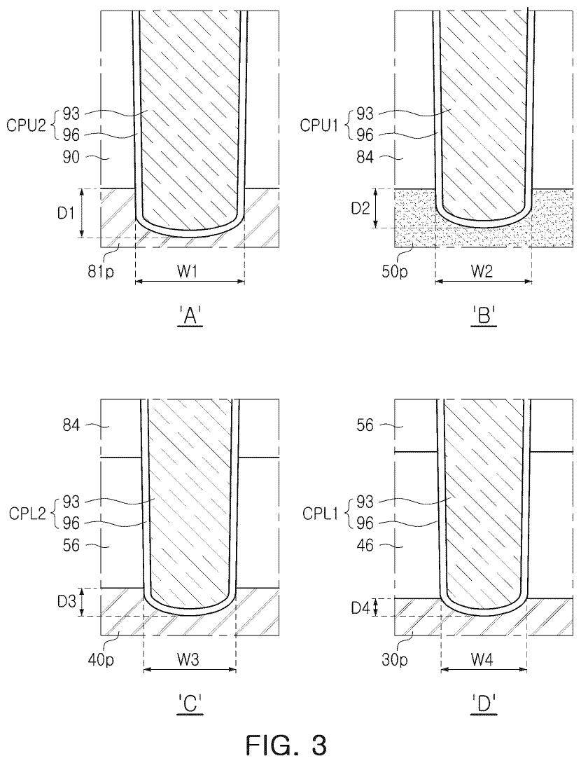

FIG. 3 is an example enlarged view of a portion of the semiconductor device illustrated in FIG. 2A.

Referring to FIGS. 2A, 2B, and 3, the cell contact plug CPC extends in the vertical direction (Z) in the cell array region (MCA) to pass through the upper interlayer insulating layer 90 and contacts the information storage structure 87. For example, the cell contact plug CPC contacts the second electrode 88c.

A peripheral contact plug CPP is disposed in the connection region EA. In some implementations, the peripheral contact plug CPP includes a first lower contact plug CPL1, a second lower contact plug CPL2, a first upper contact plug CPU1, and a second upper contact plug CPU2.

The first lower contact plug CPL1 may be connected to the first lower interconnection 30p. For example, the first lower contact plug CPL1 may extend in the vertical direction Z and pass through the upper interlayer insulating layer 90, the bit line insulating layer 56, and the second lower insulating layer 46, and may contact the first lower interconnection 30p. The first lower contact plug CPL1 may be electrically connected to at least one of the first lower interconnections 30p.

The second lower contact plug CPL2 may be connected to the second lower interconnection 40p. For example, the second lower contact plug CPL2 may extend in the vertical direction Z to pass through the upper interlayer insulating layer 90 and the bit line insulating layer 56, and may contact the second lower interconnection 40p. The second lower contact plug CPL2 may be electrically connected to at least one of the second lower interconnections 40p. The height of each of the first lower contact plug CPL1 and the second lower contact plug CPL2 may be greater than the sum of the height of the upper structure US and the height of the information storage structure 87.

The first upper contact plug CPU1 may be connected to the first upper interconnection 50p. For example, the first upper contact plug CPU1 may extend in the vertical direction Z to pass through the upper interlayer insulating layer 90 and the bit line insulating layer 56, and may contact the first upper interconnection 50p. The first upper contact plug CPU1 may be electrically connected to at least one of the first upper interconnections 50p. The height of the first upper contact plug CPU1 may be higher than that of the upper structure US.

The second upper contact plug CPU2 may be connected to the second upper interconnection 81p. For example, the second upper contact plug CPU2 may extend in the vertical direction Z to pass through the upper interlayer insulating layer 90 and contact the second upper interconnection 81p. The second upper contact plug CPU2 may be electrically connected to at least one of the second upper interconnections 81p.

In some implementations, the cell contact plug CPC and the peripheral contact plug CPP are formed at the same time and may include the same material as each other. For example, the cell contact plug CPC, the first lower contact plug CPL1, the second lower contact plug CPL2, the first upper contact plug CPU1, and the second upper contact plug CPU2 may each include a metal layer 93 and a barrier layer 96 covering lower and side surfaces of the metal layer 93. The metal layer 93 may include a conductive material, such as tungsten, and the barrier layer 96 may include a conductive material, such as TiN.

Upper surfaces of the cell contact plug CPC, the first lower contact plug CPL1, the second lower contact plug CPL2, the first upper contact plug CPU1, and the second upper contact plug CPU2 may be coplanar with an upper interlayer insulating layer 90. The first lower contact plug CPL1, the second lower contact plug CPL2, the first upper contact plug CPU1, and the second upper contact plug CPU2 may each extend in the vertical direction Z from the upper surface of the upper interlayer insulating layer 90, the first lower contact plug CPL1 may have the largest height, and the second upper contact plug CPU2 may have the smallest height. The cell contact plug CPC, the first lower contact plug CPL1, the second lower contact plug CPL2, the first upper contact plug CPU1, and the second upper contact plug CPU2 may have a tapered shape having a horizontal width decreasing downwardly.

A back end of line BEOL interconnection structure (not shown) may be disposed on the upper interlayer insulating layer 90, and some of the cell contact plug CPC, the first lower contact plug CPL1, the second lower contact plug CPL2, the first upper contact plug CPU1, and the second upper contact plug CPU2 may be electrically connected to each other by the BEOL interconnection structure.

In some implementations, as illustrated in FIG. 2B, the peripheral contact plugs CPP contacting interconnections 30p, 40p, 50p, and 81p disposed on different layers are arranged in the connection region EA. Since a plurality of interconnection layers are arranged in the connection region EA, various interconnection structures may be implemented and the degree of freedom of design may increase. Accordingly, the area of the connection region EA may decrease and the size of the semiconductor device 1 may decrease.

In some implementations, horizontal widths of upper surfaces of the peripheral contact plugs CPP are the same as each other. Also, lower horizontal widths of the peripheral contact plugs CPP may be different from each other. Here, the ‘lower horizontal width’ may refer to a horizontal width of the peripheral contact plug CPP on the upper surface of the corresponding interconnections 30p, 40p, 50p, and 81p. The peripheral contact plugs CPP may have a smaller lower horizontal width as heights thereof increase. As shown in FIG. 3, the second upper contact plug CPU2, the first upper contact plug CPU1, the second lower contact plug CPL2, and the first lower contact plug CPL1 have lower horizontal widths W1, W2, W3, and W4, respectively, and the lower horizontal widths W1, W2, W3, and W4 of the second upper contact plug CPU2, the first upper contact plug CPU1, the second lower contact plug CPL2, and the first lower contact plug CPL1 may sequentially decrease (W1>W2>W3>W4).

In some implementations, depths at which the peripheral contact plugs CPP are respectively inserted into the corresponding interconnections 30p, 40p, 50p, and 81p are different from each other. For example, the second upper contact plug CPU2 may be inserted into the second upper interconnection 81p by the depth D1, the first upper contact plug CPU1 may be inserted into the first upper interconnection 50p by the depth D2, the second lower contact plug CPL2 may be inserted into the second lower interconnection 40p by the depth D3, and the first lower contact plug CPL1 may be inserted into the first lower interconnection 30p by the depth D4. The depths D1, D2, D3, and D4 inserted into the interconnections may sequentially decrease (D1>D2>D3>D4).

The arrangement structure and number of the lower interconnection layers LL1 and LL2 and the peripheral contact plugs CPP illustrated in FIG. 2A are examples and are not limited thereto. In some implementations, one or three or more lower interconnection layers are arranged.

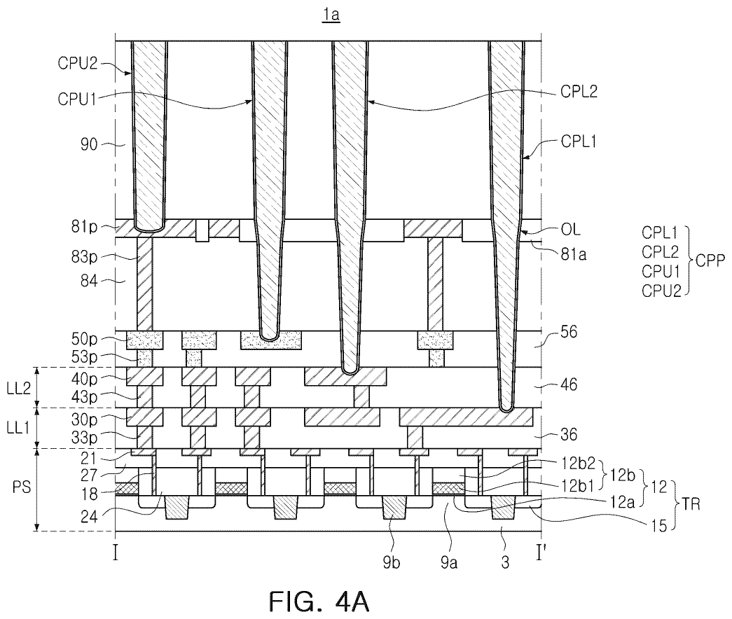

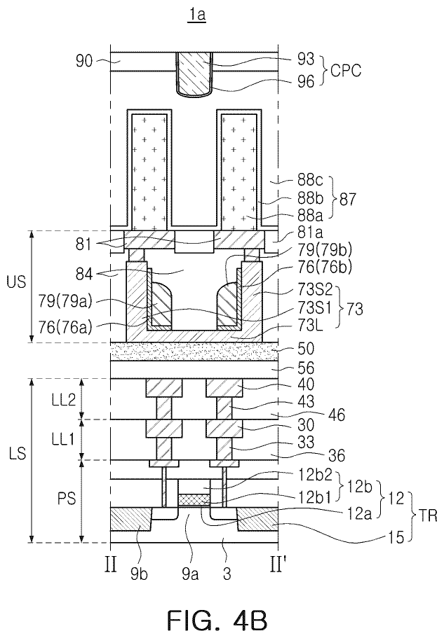

FIGS. 4A and 4B are vertical cross-sectional views of a semiconductor device according to an example implementation.

Referring to FIGS. 4A and 4B, a semiconductor device 1a includes peripheral contact plugs CPP extending from an upper surface of the upper interlayer insulating layer 90. In some implementations, the semiconductor device 1a further includes an insulating pattern 81a disposed between the second upper interconnections 81p. The insulating pattern 81a is also disposed between the upper insulating structure 84 and the upper interlayer insulating layer 90. Upper surfaces of the insulating patterns 81a are coplanar with upper surfaces of the second upper interconnections 81p. In some implementations, the insulating patterns 81a extends downwardly further than the second upper interconnections 81p. The insulating patterns 81a are also disposed between the landing pads 81.

In some implementations, the insulating pattern 81a includes a material different from that of the upper insulating structure 84 and the upper interlayer insulating layer 90. The insulating pattern 81a may include silicon boron nitride (SiBN), silicon carbon nitride (SiCN), silicon oxide (SiO₂), silicon nitride (SiN), or combinations thereof. For example, the insulating pattern 81a may include silicon nitride.

In some implementations, the peripheral contact plug CPP includes a portion in which the inclination of a side surface changes. For example, the first lower contact plug CPL1 may include an overlapping portion OL overlapping the insulating pattern 81a in a horizontal direction. A slope of the side surface of the first lower contact plug CPL1 in the overlapping portion OL may be different from a slope of the side surface of the first lower contact plug CPL1 in a portion horizontally overlapping the upper insulating structure 84 and the upper interlayer insulating layer 90. For example, the slope in the portion overlapping the upper insulating structure 84 and the upper interlayer insulating layer 90 in the horizontal direction may be steeper than the slope in the overlapping portion OL.

Similarly, the slope of the second lower contact plug CPL2 and the first upper contact plug CPU1 may change in a portion overlapping the insulating pattern 81a.

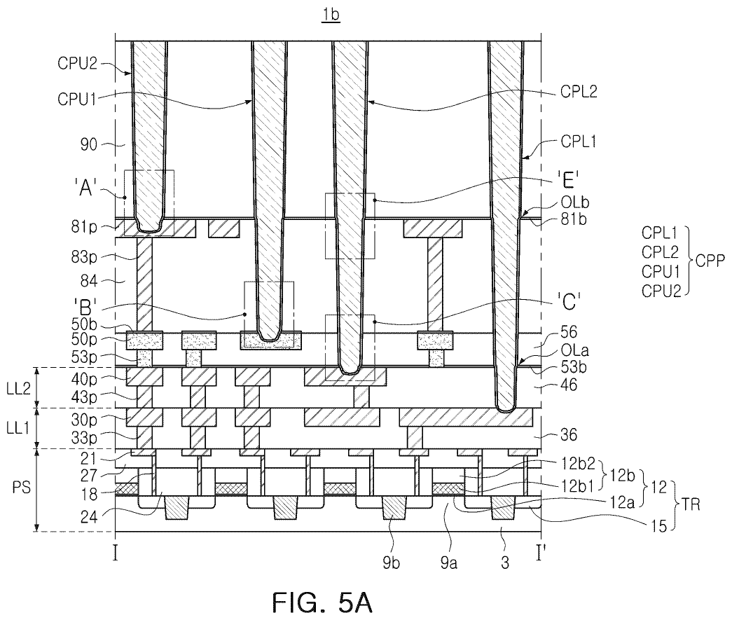

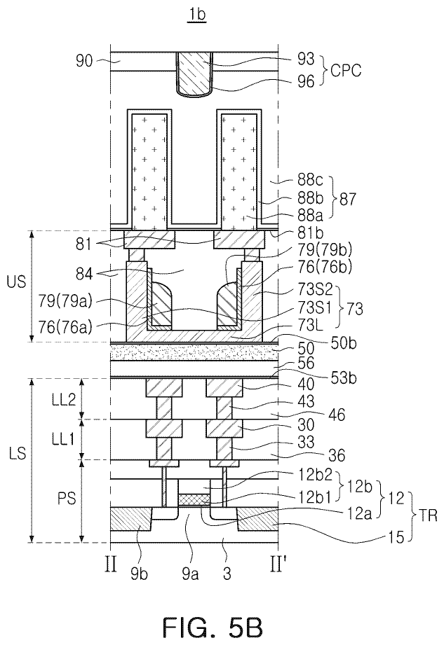

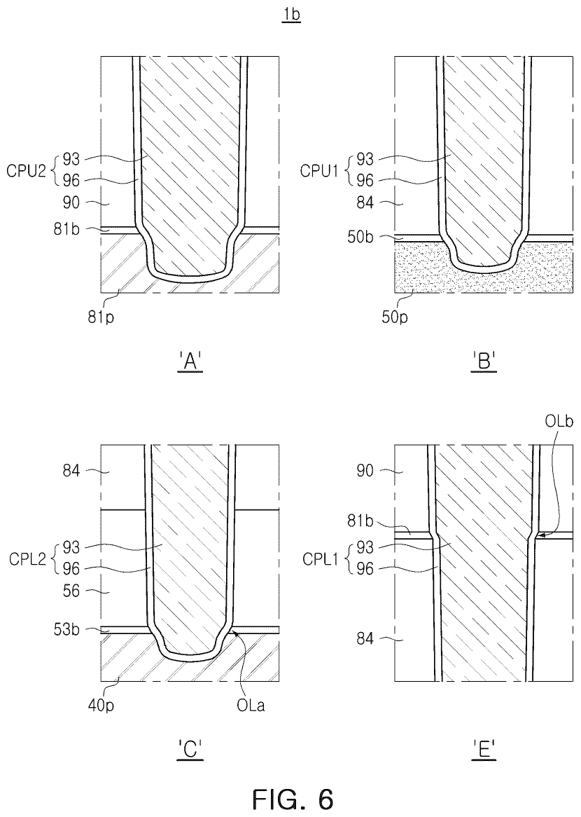

FIGS. 5A and 5B are vertical cross-sectional views of a semiconductor device according to an example implementation. FIG. 6 is an enlarged view of a portion of the semiconductor device illustrated in FIG. 5A.

Referring to FIGS. 5A, 5B and 6, a semiconductor device 1b includes peripheral contact plugs CPP extending from an upper surface of the upper interlayer insulating layer 90. In some implementations, the semiconductor device 1b further includes a lower etch stop layer 53b, a capping layer 50b, and an upper etch stop layer 81b. The lower etch stop layer 53b covers the second lower interconnection 40p and the second lower insulating layer 46 and is disposed below the bit line insulating layer 56. The capping layer 50b covers upper surfaces of the bit line 50 and the first upper interconnection 50p. The upper etch stop layer 81b covers upper surfaces of the landing pad 81 and the second upper interconnection 81p and extends in the horizontal direction.

In some implementations, the lower etch stop layer 53b, the capping layer 50b, and the upper etch stop layer 81b include a material different from that of the upper insulating structure 84 and the upper interlayer insulating layer 90. The lower etch stop layer 53b and the upper etch stop layer 81b may include silicon boron nitride (SiBN), silicon carbon nitride (SiCN), silicon nitride, or combinations thereof. The capping layer 50b may include silicon nitride.

In some implementations, the peripheral contact plug CPP includes a portion in which the slope of a side surface changes. Slopes of the first lower contact plug CPL1 and the second lower contact plug CPL2 may change in portions overlapping the lower etch stop layer 53b and the upper etch stop layer 81b in the horizontal direction, respectively. For example, the first lower contact plug CPL1 may include a first overlapping portion OLa horizontally overlapping the lower etch stop layer 53b and a second overlapping portion OLb horizontally overlapping the upper etch stop layer 81b. The slope of the side surface of the first lower contact plug CPL1 in the first overlapping portion OLa and the second overlapping portion OLb may be different from the slope of the side surface of the first lower contact plug CPL1 in the portion horizontally overlapping the upper insulating structure 84 and the upper interlayer insulating layer 90.

The slope of the first upper contact plug CPU1 may change in inclination in a portion overlapping the capping layer 50b and the upper etch stop layer 81b in the horizontal direction. The slope of the second upper contact plug CPU2 may change in a portion overlapping the upper etch stop layer 81b in the horizontal direction.

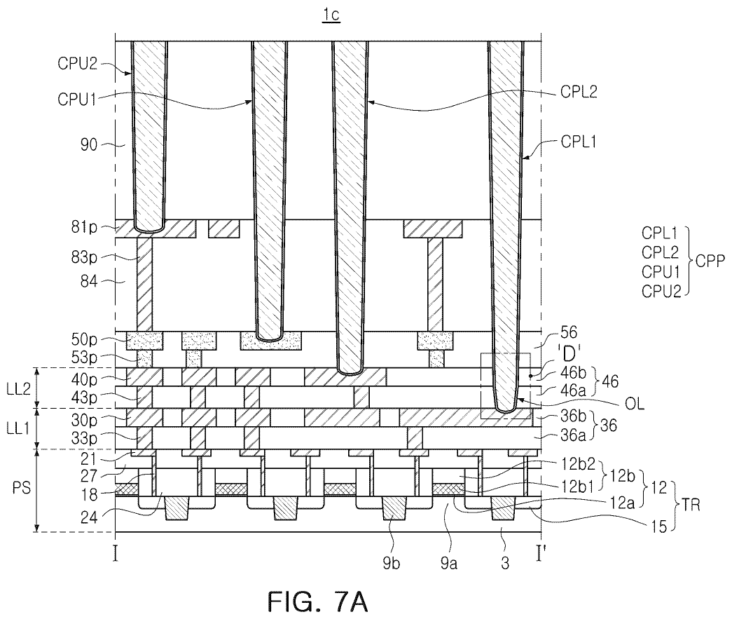

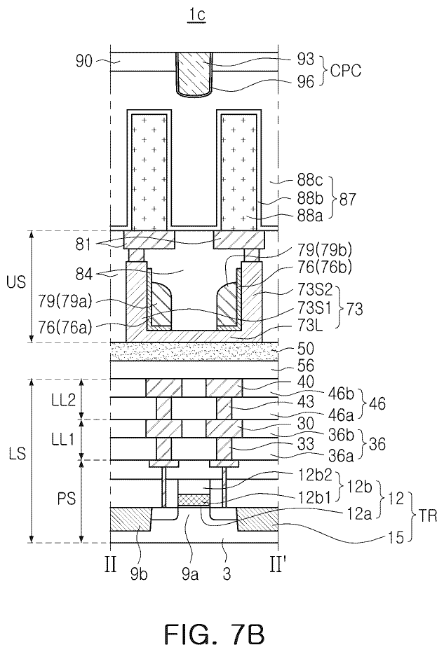

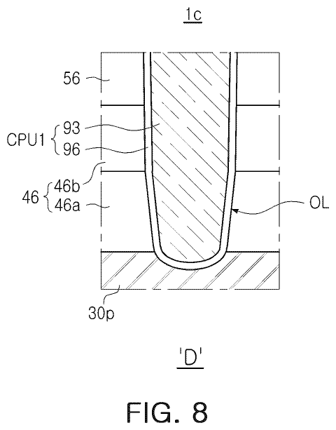

FIGS. 7A and 7B are vertical cross-sectional views of a semiconductor device according to an example implementation. FIG. 8 is an enlarged view of a portion of the semiconductor device illustrated in FIG. 7A.

Referring to FIGS. 7A, 7B, and 8, a semiconductor device 1c includes peripheral contact plugs CPP extending from an upper surface of the upper interlayer insulating layer 90. In some implementations, the first lower insulating layer 36 of the first lower interconnection layer LL1 includes a first material layer 36a covering a side surface of the first lower plug 33p and a second material layer 36b covering a side surface of the first lower interconnection 30p. The second lower insulating layer 46 includes a first material layer 46a covering a side surface of the second lower plug 43p and a second material layer 46b covering a side surface of the second lower interconnection 40p.

The first material layers 36a and 46a include materials different from those of the second material layers 36b and 46b. For example, the first material layers 36a and 46a include SiCOH, SiBN, SiCN, SiN, or combinations thereof, and the second material layers 36b and 46b include silicon oxide.

In some implementations, the first lower contact plug CPL1 includes a portion in which a slope of a side surface changes. For example, the first lower contact plug CPL1 may include an overlapping portion OL overlapping the first material layer 46a in the horizontal direction. The slope of the side surface of the first lower contact plug CPL1 in the overlapping portion OL may be different from the slope of the side surface of the first lower contact plug CPL1 in the portion overlapping the second material layer 46b in the horizontal direction. For example, the slope in the portion overlapping the second material layer 46b in the horizontal direction may be steeper than the slope in the overlapping portion OL.

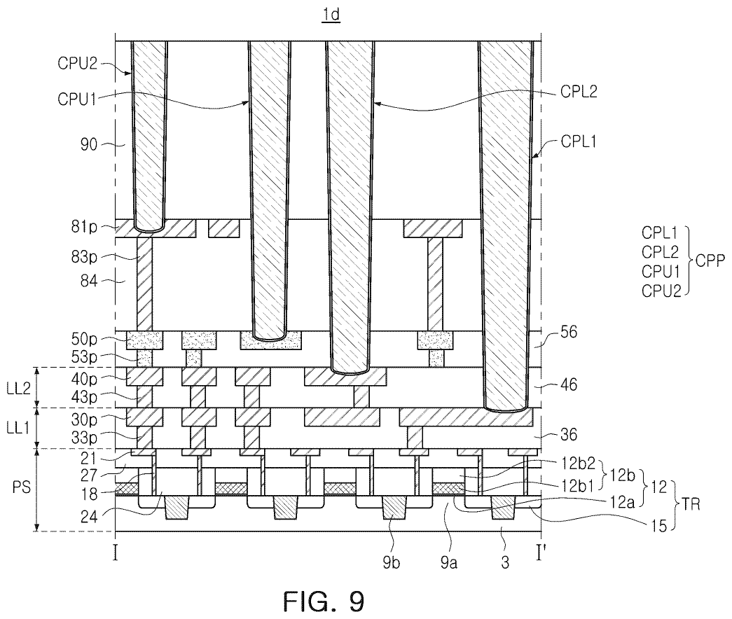

FIG. 9 is a vertical cross-sectional view of a semiconductor device according to an example implementation.

Referring to FIG. 9, a semiconductor device Id includes peripheral contact plugs CPP extending from an upper surface of the upper interlayer insulating layer 90. In some implementations, horizontal widths of upper surfaces of the peripheral contact plugs CPP are different from each other. For example, the horizontal width of the upper surfaces of the peripheral contact plugs CPP increases as the heights thereof increase. The horizontal width of the upper surface of the second upper contact plug CPU2 may be the smallest, and the horizontal width of the upper surface of the first lower contact plug CPL1 may be the largest.

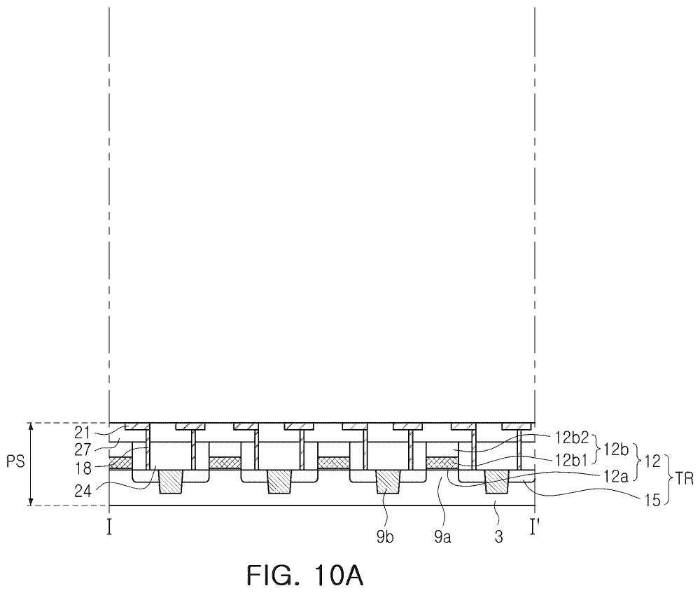

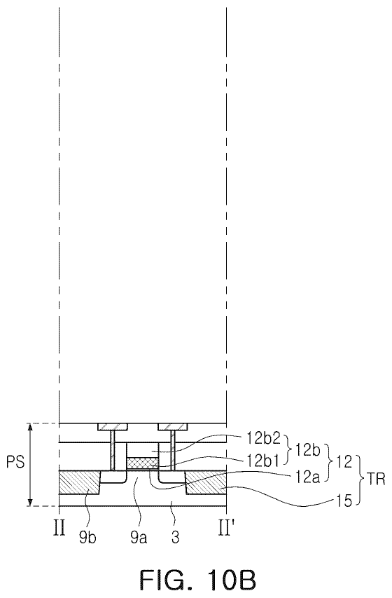

FIGS. 10A to 15B are vertical cross-sectional views illustrating a sequential process of a method of manufacturing a semiconductor device according to an example implementation. Specifically, FIGS. 10A, 11A, 12A, 13A, 14A, and 15A are vertical cross-sectional views illustrating the connection region EA and corresponding to FIG. 2A. FIGS. 10B, 11B, 12B, 13B, 14B, and 15B are vertical cross-sectional views illustrating the cell array region MCA and corresponding to FIG. 2B.

Referring to FIGS. 10A and 10B, a peripheral circuit layer PS is formed. As described above with reference to FIGS. 2A and 2B, the peripheral circuit layer PS includes the substrate 3, the circuit element TR on the substrate 3, the peripheral interconnection 21 electrically connected to the circuit element TR, the first peripheral insulating layer 24 surrounding the side surface of the peripheral plug 18 and the side surface of the circuit element TR, and the second peripheral insulating layer 27 surrounding the peripheral interconnection 21 and the peripheral plug 18.

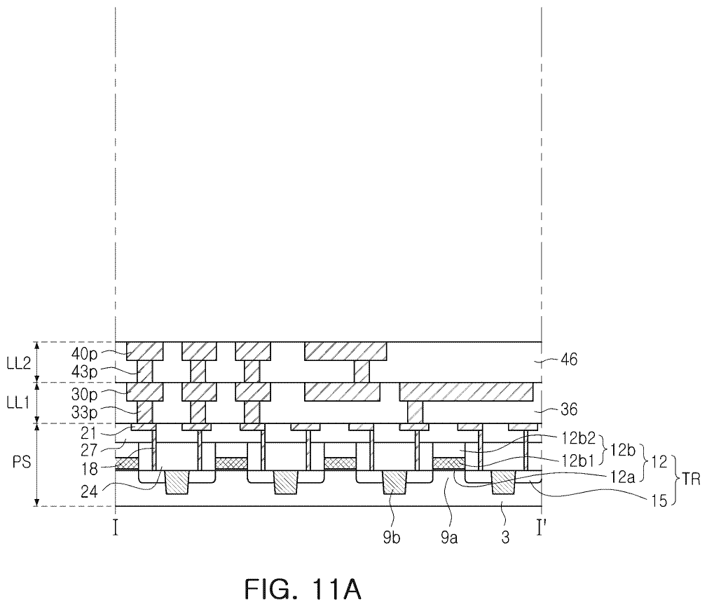

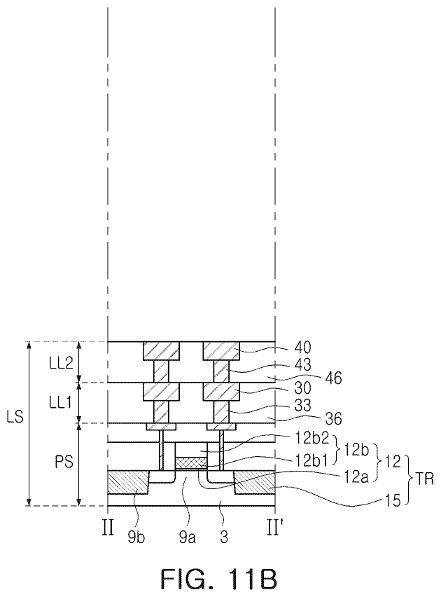

Referring to FIGS. 11A and 11B, the first lower interconnection layer LL1 and the second lower interconnection layer LL2 are formed on the peripheral circuit layer PS. Forming the first lower interconnection layer LL1 includes forming an insulating material on the peripheral circuit layer PS, patterning the insulating material to form an opening, depositing a conductive material in the opening, and patterning the conductive material. As described above with reference to FIGS. 2A and 2B, the first lower interconnection layer LL1 includes the first lower interconnections 30 and 30p, the first lower plugs 33 and 33p, and the first lower insulating layer 36.

The second lower interconnection layer LL2 is formed on the first lower interconnection layer LL1 and is formed by a method the same as or similar to that of the first lower interconnection layer LL1. As described above with reference to FIGS. 2A and 2B, the second lower interconnection layer LL2 includes the second lower interconnections 40 and 40p, the second lower plugs 43 and 43p, and the second lower insulating layer 46.

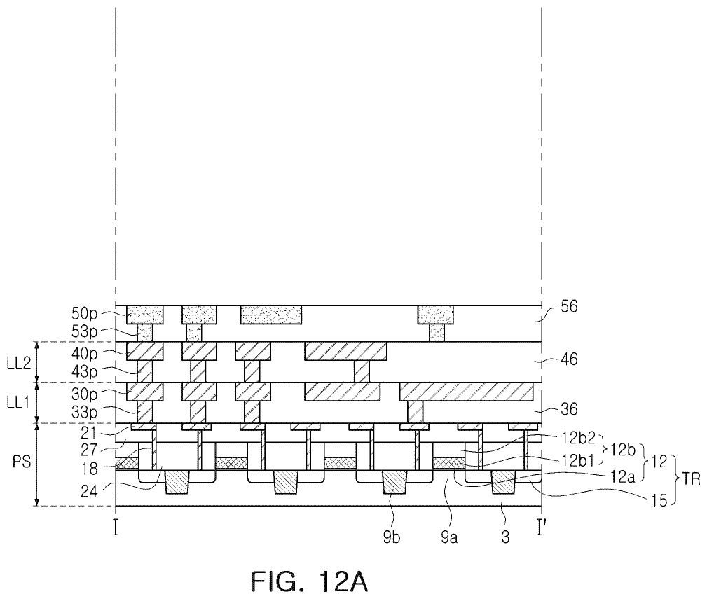

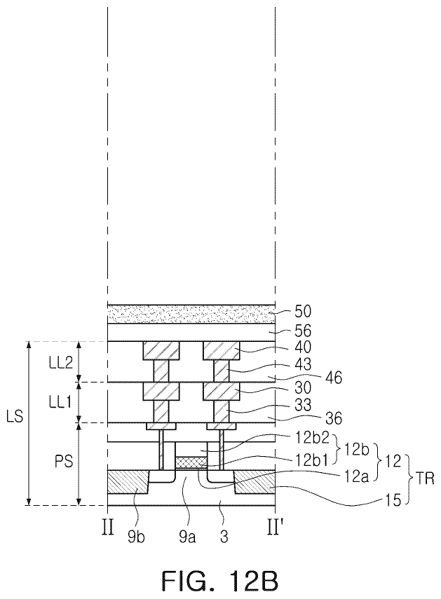

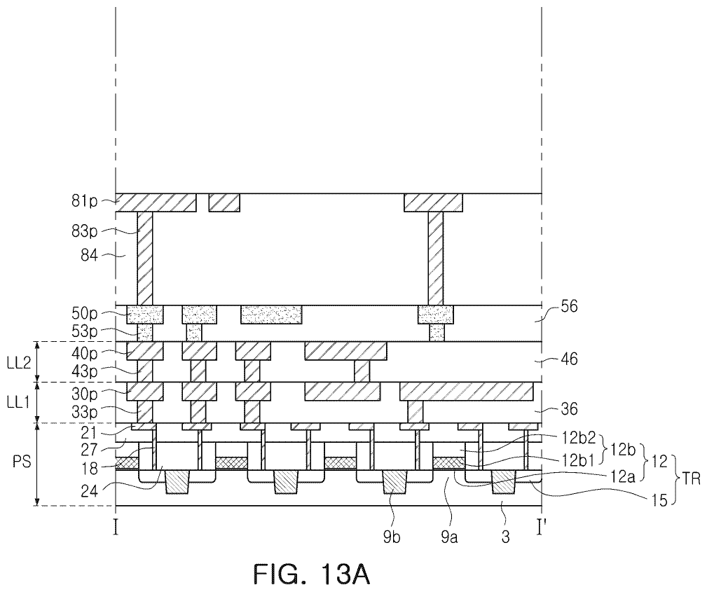

Referring to FIGS. 12A and 12B, the bit line 50, the cell connection plug 53, and the bit line insulating layer 56 are formed in the cell array region MCA. The cell connection plug 53 may be formed by forming a conductive material on the second lower interconnection layer LL2 and patterning the conductive material. The bit line 50 may be formed on the cell connection plug 53 and may extend in the first horizontal direction X.

In the connection region EA, the first upper interconnection 50p and the first peripheral plug 53p may be formed on the second lower interconnection layer LL2. The first upper interconnection 50p and the first peripheral plug 53p may be formed simultaneously with the bit line 50 and the cell connection plug 53 and may be formed of the same material as those of the bit line 50 and the cell connection plug 53.

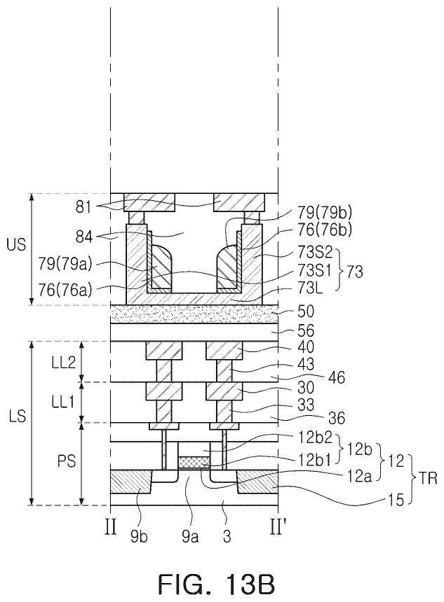

Referring to FIGS. 13A and 13B, the upper structure US is formed on the bit lines 50 and the bit line insulating layer 56 in the cell array region MCA. As illustrated in FIG. 2B, the upper structure US includes the channel structure 73, the dielectric structure 76, the word lines 79, the landing pads 81, and the upper insulating structure 84. However, the shape of the upper structure US is not limited to the example implementation illustrated in FIG. 2B and may be variously modified.

In the connection region EA, the second upper interconnection 81p and the second peripheral plug 83p may be formed on the first upper interconnection 50p and the bit line insulating layer 56. In some implementations, the second upper interconnection 81p and the second peripheral plug 83p are formed simultaneously with the landing pads 81 and may include the same material as that of the landing pads 81. The upper insulating structure 84 may surround the second upper interconnection 81p and the second peripheral plug 83p.

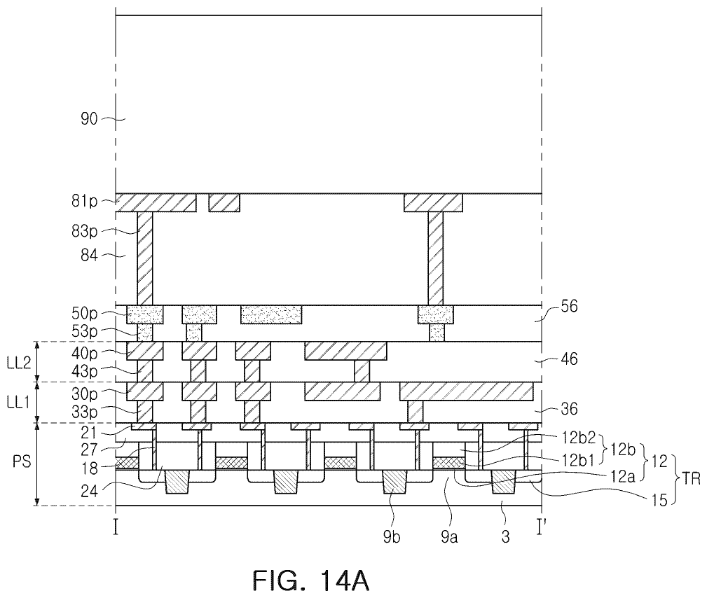

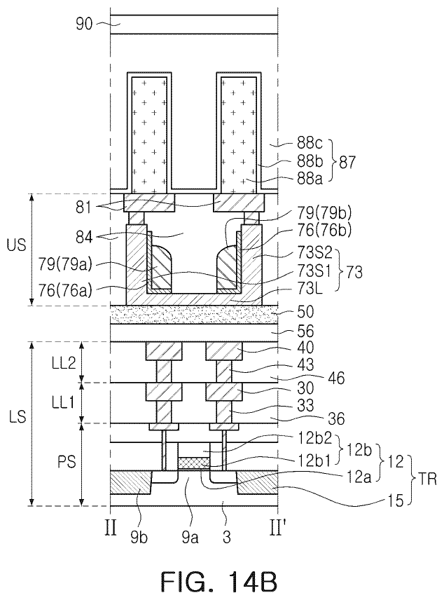

Referring to FIGS. 14A and 14B, the information storage structure 87 is formed on the upper structure US in the cell array region MCA. As described above with reference to FIGS. 2A and 2B, the information storage structure 87 includes first electrodes 88a electrically connected to and in contact with the landing pads 81, and the second electrode 88c on the first electrodes 88a, and the dielectric layer 88b between the first electrodes 88a and the second electrode 88c.

The upper interlayer insulating layer 90 may be formed to cover the information storage structure 87 in the cell array region MCA. The upper interlayer insulating layer 90 may cover the second upper interconnection 81p in the connection region EA.

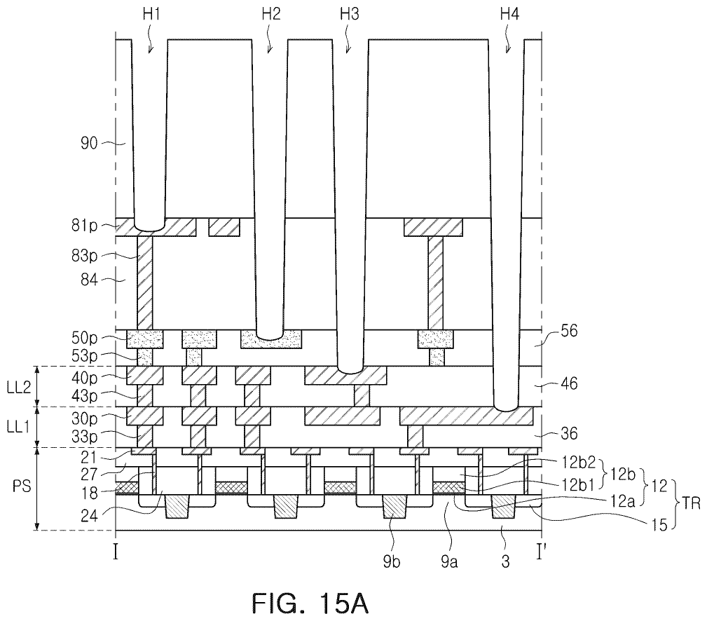

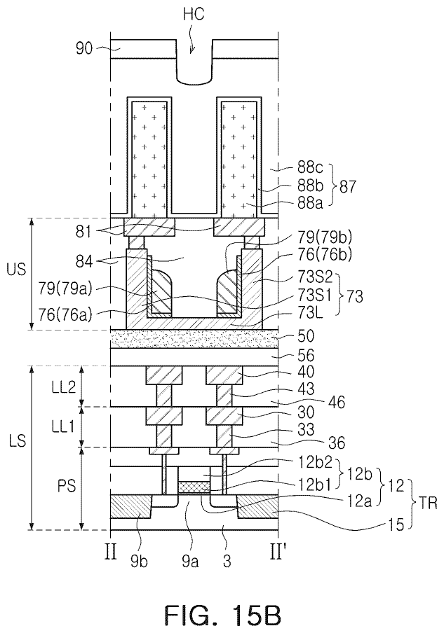

Referring to FIGS. 15A and 15B, a cell contact hole HC is formed in the cell region, and a second upper contact hole H1, a first upper contact hole H2, a second lower contact hole H3, and a first lower contact hole H4 are formed in the connection region EA. The cell contact hole HC, the second upper contact hole H1, the first upper contact hole H2, the second lower contact hole H3, and the first lower contact hole H4 expose upper surfaces of the second electrode 88c, upper surfaces of the second upper interconnection 81p, the first upper interconnection 50p, the second lower interconnection 40p, and the first lower interconnection 30p, respectively.

The cell contact hole HC, the second upper contact hole H1, the first upper contact hole H2, the second lower contact hole H3, and the first lower contact hole H4 may be simultaneously formed by performing an anisotropic etching process. In some implementations, horizontal widths at upper ends of the cell contact hole HC, the second upper contact hole H1, the first upper contact hole H2, the second lower contact hole H3, and the first lower contact hole H4 are the same as each other, but are not limited thereto.

Referring back to FIGS. 2A and 2B, the barrier layer 96 is conformally formed in the cell contact hole HC, the second upper contact hole H1, the first upper contact hole H2, the second lower contact hole H3, and the first lower contact hole H4, and the barrier layer 96 is filled with the metal layer 93 to form each of the cell contact plug CPC, the second upper contact plug CPU2, the first upper contact plug CPU1, the second lower contact plug CPL2, and the first lower contact plug CPL1.

The cell contact plug CPC, the second upper contact plug CPU2, the first upper contact plug CPU1, the second lower contact plug CPL2, and the first lower contact plug may extend from the upper surface of the upper interlayer insulating layer 90 to contact the second electrode 88c, the second upper interconnection 81p, the first upper interconnection 50p, the second lower interconnection 40p, and the first lower interconnection 30p, respectively.

According to example implementations of the concepts described herein, peripheral contact plugs contacting the interconnections arranged on different layers are arranged. Since the plurality of interconnection layers are arranged in the connection region, various interconnection structures are implemented and the degree of freedom of design increases. Accordingly, the area of the connection region decreases and the size of the semiconductor device is reduced.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While example implementations have been illustrated and described above, it will be apparent to those skilled in the art that modifications and variations could be made without departing from the scope of the present concepts as defined by the appended claims.

What is claimed is:

1. A semiconductor device comprising:
a substrate including a cell array region and a connection region;
a peripheral circuit layer disposed on the substrate, the peripheral circuit layer including a circuit element;
a bit line disposed on the peripheral circuit layer that is in the cell array region;
a first upper interconnection disposed on the connection region of the substrate, wherein the first upper interconnection is at a same height as the bit line is from the substrate;
at least one lower interconnection layer disposed between the peripheral circuit layer and the bit line and between the peripheral circuit layer and the first upper interconnection;
a bit line insulating layer surrounding the bit line in the cell array region and surrounding the first upper interconnection in the connection region;
an upper structure disposed on the bit line and the first upper interconnection, the upper structure including an upper insulating structure;
an information storage structure disposed on the upper structure that is in the cell array region; and
a plurality of lower contact plugs electrically connected to the at least one lower interconnection layer through the bit line insulating layer, the plurality of lower contact plugs disposed in the connection region.

2. The semiconductor device of claim 1, wherein the plurality of lower contact plugs pass through the upper insulating structure.

3. The semiconductor device of claim 1, comprising:
an upper interlayer insulating layer covering the information storage structure in the cell array region and covering the upper insulating structure in the connection region,
wherein the plurality of lower contact plugs pass through the upper interlayer insulating layer.

4. The semiconductor device of claim 1, wherein
the at least one lower interconnection layer includes a first lower interconnection layer and a second lower interconnection layer, the second lower interconnection layer disposed on the first lower interconnection layer,
the first lower interconnection layer includes a plurality of first lower interconnections,
the second lower interconnection layer includes a plurality of second lower interconnections, and
the plurality of lower contact plugs include a first lower contact plug, the first lower contact plug passing through the second lower interconnection layer and contacting one first lower interconnection of the plurality of first lower interconnections.

5. The semiconductor device of claim 4, wherein at least one first lower interconnection of the plurality of first lower interconnections is electrically connected to at least one second lower interconnection of the plurality of second lower interconnections, and one or more first lower interconnections of the plurality of first lower interconnections are electrically connected to the first lower contact plug.

6. The semiconductor device of claim 4, wherein the plurality of lower contact plugs include a second lower contact plug contacting one second lower interconnection of the plurality of second lower interconnections.

7. The semiconductor device of claim 6, wherein a width of an upper surface of the first lower contact plug is greater than a width of an upper surface of the second lower contact plug.

8. The semiconductor device of claim 6, wherein a width of an upper surface of the first lower contact plug is equal to a width of an upper surface of the second lower contact plug.

9. The semiconductor device of claim 8, wherein a lower width of the first lower contact plug is smaller than a lower width of the second lower contact plug, the lower width of the first lower contact plug is a width of the first lower contact plug on an upper surface of the first lower interconnection, and the lower width of the second lower contact plug is a width of the second lower contact plug on an upper surface of the second lower interconnection.

10. The semiconductor device of claim 8, wherein a depth at which the first lower contact plug extends into the first lower interconnection is less than a depth at which the second lower contact plug extends into the second lower interconnection.

11. The semiconductor device of claim 4, comprising:
an insulating pattern disposed on the upper insulating structure, the insulating pattern including a material different from a material of the upper insulating structure,
wherein a slope of a side surface of the first lower contact plug in a portion in which the first lower contact plug overlaps the insulating pattern in a horizontal direction is different from a slope of a side surface of the first lower contact plug in a portion in which the first lower contact plug overlaps the upper insulating structure in the horizontal direction.

12. The semiconductor device of claim 4, further comprising:
a lower etch stop layer disposed below the bit line insulating layer; and
an upper etch stop layer disposed on the upper structure,
wherein a slope of a side surface of the first lower contact plug changes in a portion overlapping the lower etch stop layer in a horizontal direction, and the slope of the side surface of the first lower contact plug changes in a portion overlapping the upper etch stop layer in the horizontal direction.

13. The semiconductor device of claim 4, wherein
the second lower interconnection layer includes a first material layer and a second material layer, the second material layer including a material different from a material of the first material layer and covering a plurality of side surfaces of the plurality of second lower interconnections, and
a slope of a side surface of the first lower contact plug in a portion in which the first lower contact plug overlaps the first material layer in a horizontal direction is different from a slope of a side surface of the first lower contact plug in a portion in which the first lower contact plug overlaps the second material layer in the horizontal direction.

14. A semiconductor device comprising:
a substrate including a cell array region and a connection region;
a peripheral circuit layer disposed on the substrate, the peripheral circuit layer including a circuit element;
a bit line disposed on the peripheral circuit layer that is in the cell array region;
a first upper interconnection disposed on the connection region of the substrate, wherein the first upper interconnection is on a same height as the bit line is from the substrate;
a lower interconnection layer disposed between the peripheral circuit layer and the bit line and between the peripheral circuit layer and the first upper interconnection, the lower interconnection layer including a lower interconnection;
a bit line insulating layer surrounding the bit line in the cell array region and surrounding the first upper interconnection in the connection region;
an upper structure disposed on the bit line and the first upper interconnection, the upper structure including an upper insulating structure;
an information storage structure disposed on the upper structure that is in the cell array region;
an upper interlayer insulating layer covering the information storage structure in the cell array region and covering the upper insulating structure in the connection region;
a lower contact plug extending in a vertical direction from an upper surface of the upper interlayer insulating layer in the connection region, passing through the bit line insulating layer, and contacting the lower interconnection; and
a first upper contact plug extending in the vertical direction from the upper surface of the upper interlayer insulating layer and contacting the first upper interconnection.

15. The semiconductor device of claim 14, wherein a width of an upper surface of the lower contact plug is equal to a width of an upper surface of the first upper contact plug.

16. The semiconductor device of claim 15, wherein a lower width of the lower contact plug is less than a lower width of the first upper contact plug, the lower width of the lower contact plug is a width of the lower contact plug on an upper surface of the lower interconnection, and the lower width of the first upper contact plug is a width of the first upper contact plug on an upper surface of the first upper interconnection.

17. The semiconductor device of claim 14, wherein the first upper contact plug passes through the upper insulating structure and the upper interlayer insulating layer.

18. The semiconductor device of claim 14, wherein a height of the first upper contact plug is greater than a height of the upper structure.

19. A semiconductor device comprising:
a substrate including a cell array region and a connection region;
a peripheral circuit layer disposed on the substrate, the peripheral circuit layer including a circuit element;
a first lower interconnection layer disposed on the peripheral circuit layer, the first lower interconnection layer including a first lower interconnection;
a second lower interconnection layer disposed on the first lower interconnection layer, the second lower interconnection layer including a second lower interconnection layer;
a bit line disposed on the second lower interconnection layer that is in the cell array region;
a first upper interconnection disposed on the connection region of the substrate, wherein the first upper interconnection is on a same height as the bit line is from the substrate;
a bit line insulating layer surrounding the bit line in the cell array region and surrounding the first upper interconnection in the connection region;
an upper structure disposed on the bit line and the first upper interconnection, the upper structure including a landing pad and an upper insulating structure surrounding the landing pad;
a second upper interconnection disposed on the connection region of the substrate, wherein the second upper interconnection is on a same height as the landing pad is from the substrate;
an information storage structure disposed on the upper structure that is in the cell array region;
an upper interlayer insulating layer covering the information storage structure in the cell array region and covering the upper insulating structure in the connection region; and
a first lower contact plug passing through the upper interlayer insulating layer, the upper insulating structure, and the bit line insulating layer, the first lower contact plug contacting the first lower interconnection in the connection region.

20. The semiconductor device of claim 19, comprising a first upper contact plug passing through the upper interlayer insulating layer and the upper insulating structure, the first upper contact plug contacting the first upper interconnection in the connection region.
